(19) United States
(12) Patent Application Publication
(10) Pub. No.: US 2025/0386630 A1
(43) Pub. Date: Dec. 18, 2025

(54) MICRO LED ELEMENT, MICRO LED DISPLAY PANEL AND DISPLAY DEVICE

(71) Applicant: JADE BIRD DISPLAY (SHANGHAI) LIMITED, SHANGHAI (CN)

(72) Inventors: Zhichen GU, Shanghai (CN); Weisin TAN, Shanghai (CN)

(21) Appl. No.: 19/235,593

(22) Filed: Jun. 12, 2025

(30) Foreign Application Priority Data
Jun. 14, 2024 (WO) PCT/CN2024/099217

(51) Int. Cl. H10H 29/14; H10H 29/80

(52) U.S. Cl. CPC H10H 29/142; H10H 29/8323; H10H 29/8325; H10H 29/842; H10H 29/872

(57) ABSTRACT

A micro LED element, a micro LED display panel, and a display device are provided. The micro LED element includes: a first semiconductor layer, a light emitting layer, and a second semiconductor layer stacked from top down, wherein the first semiconductor layer includes: a main part for passing light generated by the light emitting layer; and an extension part for connecting to the extension part of the first semiconductor layer of an adjacent micro LED element; and a metal contact including a plurality of metal particles arranged on or above the extension part of the first semiconductor layer.

### CROSS-REFERENCE TO RELATED APPLICATIONS

The present disclosure claims the benefit of priority to PCT Application No. PCT/CN2024/099217, filed on Jun. 14, 2024, which is incorporated herein by reference in its entirety.

### TECHNICAL FIELD

The present disclosure generally relates to micro display technology, and more particularly, to a micro light emitting diode (LED) element, a micro LED display panel, and a display device.

### BACKGROUND

Inorganic micro pixel light emitting diodes, also referred to as micro light emitting diodes, micro LEDs, or u-LEDs, become more important since they are used in various applications including self-emissive micro-displays, visible light communications, and optogenetics. The micro LEDs have higher output performance than conventional LEDs because of better strain relaxation, improved light extraction efficiency, and uniform current spreading. Compared with conventional LEDs, the micro LEDs also exhibit several advantages, such as improved thermal effects, faster response rate, larger working temperature range, higher resolution, wider color gamut, higher contrast, lower power consumption, and operability at higher current density.

A micro LED display panel is manufactured by integrating an array of thousands or even millions of micro LEDs with an integrated circuit (IC) back panel. In conventional techniques, a metal contact for increasing electrical conductivity may be arranged on the top surface of a micro LED. Since the metal contact is arranged in the emitting path of light generated by the micro LED, it may deteriorate the displaying quality of the micro LED. Therefore, there is a need for improving the displaying quality of micro LEDs.

### SUMMARY OF THE DISCLOSURE

Some embodiments of the present disclosure provide a micro LED element. The micro LED element includes: a first semiconductor layer, a light emitting layer, and a second semiconductor layer stacked from top down, wherein the first semiconductor layer includes: a main part for passing light generated by the light emitting layer; and an extension part for connecting to the extension part of the first semiconductor layer of an adjacent micro LED element; and a metal contact comprising a plurality of metal particles conductively coupled to the top surface of arranged on or above the extension part of the first semiconductor layer.

Some embodiments of the present disclosure provide a micro LED display panel. The micro LED display panel includes an integrated circuit (IC) backplane including a common pad and a plurality of bottom contacts; and a plurality of micro LED elements, each according to any of the micro LED described herein, disposed on a top surface of the IC backplane, each of the micro LED elements including a transparent conductive layer formed on a top surface of the first semiconductor layer; and a contact pad conductively coupled to the second semiconductor layer, wherein: the transparent conductive layer is conductively coupled to the common pad; and the contact pad is formed to contact a corresponding bottom contact of the plurality of bottom contacts.

Some embodiments of the present disclosure provide a display device. The display device includes any of the micro LED described herein or any of the micro LED display panels described herein.

### BRIEF DESCRIPTION OF THE DRAWINGS

Embodiments and various aspects of the present disclosure are illustrated in the following detailed description and the accompanying figures. Various features shown in the figures are not drawn to scale.

FIG. 1 illustrates a structural diagram showing a sectional view of an exemplary micro LED element, according to some embodiments of the present disclosure.

FIG. 2A illustrates a structural diagram showing a sectional view of an exemplary micro LED display panel, according to some embodiments of the present disclosure.

FIG. 2B illustrates a structural diagram showing a top view of an exemplary micro LED display panel, according to some embodiments of the present disclosure.

FIG. 3A illustrates a structural diagram showing a sectional view of another exemplary micro LED element, according to some embodiments of the present disclosure.

FIG. 3B illustrates a structural diagram showing a sectional view of another exemplary micro LED element, according to some embodiments of the present disclosure.

FIG. 3C illustrates a structural diagram showing a sectional view of another exemplary micro LED element, according to some embodiments of the present disclosure.

FIG. 4 illustrates a structural diagram showing a sectional view of another exemplary micro LED display panel, according to some embodiments of the present disclosure.

FIG. 5A illustrates a structural diagram showing a top view of another exemplary micro LED display panel, according to some embodiments of the present disclosure.

FIG. 5B illustrates a structural diagram showing a top view of another exemplary micro LED display panel, according to some embodiments of the present disclosure.

FIG. 5C illustrates a structural diagram showing a top view of another exemplary micro LED display panel, according to some embodiments of the present disclosure.

FIG. 6 illustrates a structural diagram showing a sectional view of another exemplary micro LED display panel, according to some embodiments of the present disclosure.

FIG. 7 illustrates a structural diagram showing a sectional view of another exemplary micro LED element, according to some embodiments of the present disclosure.

FIG. 8 illustrates a structural diagram showing a sectional view of another exemplary micro LED display panel, according to some embodiments of the present disclosure.

FIG. 9 illustrates a structural diagram showing a sectional view of another exemplary micro LED element, according to some embodiments of the present disclosure.

FIG. 10 illustrates a structural diagram showing a sectional view of another exemplary micro LED display panel, according to some embodiments of the present disclosure.

FIG. 11 illustrates a structural diagram showing a sectional view of another exemplary micro LED display panel, according to some embodiments of the present disclosure.

FIG. 12 illustrates an exemplary display device, according to some embodiments of the present disclosure.

FIG. 13 illustrates another exemplary display device, according to some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. Particular aspects of the present disclosure are described in greater detail below. The terms and definitions provided herein control, if in conflict with terms and/or definitions incorporated by reference.

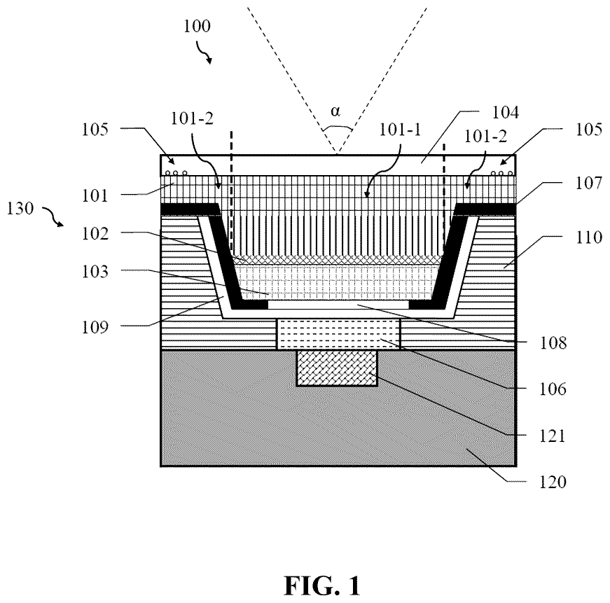

FIG. 1 illustrates a structural diagram showing a sectional view of an exemplary micro LED element 100, according to some embodiments of the present disclosure. Referring to FIG. 1, micro LED element 100 includes a first semiconductor layer 101, a light emitting layer 102, and a second semiconductor layer 103. First semiconductor layer 101, light emitting layer 102, and second semiconductor layer 103 are stacked from top down to form a mesa 130. The sidewall of mesa 130 is inclined. First semiconductor layer 101 includes a main part 101-1 and an extension part 101-2. Main part 101-1 and extension part 101-2 of first semiconductor layer 101 are illustrated as divided by the dashed lines shown in FIG. 1. Main part 101-1 is situated directly above light emitting layer 102 and configured to pass light generated by light emitting layer 102. Extension part 101-2 can be connected to extension part 101-2 of first semiconductor layer 101 of an adjacent micro LED element (not shown).

In some embodiments, second semiconductor layer 103 can be a P-type epitaxial layer or an N-type epitaxial layer. First semiconductor layer 101 is an N-type epitaxial layer or a P-type epitaxial layer. A material of first semiconductor layer 101 is selected from one or more of GaN, InGaN, AlInGaN, AlGaN, GaP, AlGaInP, or AlInP. Light emitting layer 102 is a quantum well layer. A material of light emitting layer 102 is selected from one or more of InGaN, AlGaN, AlInGaN, InGaP or AlGaInP. First semiconductor layer 101 and second semiconductor layer 103 have opposite conductive types. That is, if first semiconductor layer 101 is a P-type epitaxial layer, then second semiconductor layer 103 is an N-type epitaxial layer; and if first semiconductor layer 101 is an N-type epitaxial layer, then second semiconductor layer 103 is a P-type epitaxial layer. A material of second semiconductor layer 103 is selected from one or more of AllnP, AlGaInP, GaP, GaN, InGaN, AlInGaN or AlGaN.

In some embodiments, micro LED element 100 includes a transparent conductive layer 104 formed on a top surface of first semiconductor layer 101 and conductively coupled to first semiconductor layer 101. In some embodiments, transparent conductive layer 104 is provided as a TCO (transparent conductive oxide) layer, for example, an ITO (Indium Tin Oxide) layer, an AZO (Aluminium doped Zinc Oxide) layer, a GZO (Gallium doped Zinc Oxide), an ATO (Antimony doped Tin Oxide) layer, an FTO (Fluorine doped Tin Oxide) layer, or the like. Transparent conductive layer 104 is connected to an electrode (not shown, e.g., a common pad) of an IC (integrated circuit) backplane 120. Micro LED element 100 further includes a contact pad 106 that is conductively coupled to second semiconductor layer 103 and connected to an electrode 121 (e.g., a Cu pad) of IC backplane 120. Hence, transparent conductive layer 104 and contact pad 106 are respectively connected to two electrodes of IC backplane 120 either directly or indirectly. This enables first semiconductor layer 101 and second semiconductor layer 103 to receive signals from IC backplane 120 via transparent conductive layer 104 and contact pad 106, respectively. As a consequence, light emitting layer 102 between first semiconductor layer 101 and second semiconductor layer 103 can be driven by IC backplane 120.

In addition, micro LED element 100 may include a metal contact 105 that can be arranged on extension part 101-2 of first semiconductor layer 101 and embedded in transparent conductive layer 104. Thus, metal contact 105 can be used to improve current spreading across a whole micro LED array formed by micro LED elements 100 and can provide an ohmic contact to increase electrical conductivity between first semiconductor layer 101 and transparent conductive layer 104. As illustrated in FIG. 1, metal contact 105 includes a plurality of metal particles (also referred to as a “metal agglomeration”) formed on and conductively coupled to a top surface of first semiconductor layer 101. In some embodiments, the metal particles may be generated by heating a metal pad into cohesive units, which are denoted by hollow circles in FIG. 1. With the introduction of metal contact 105 composed of metal particles, it is possible to maintain current spreading across the whole micro LED array formed by micro LED elements 100.

Moreover, the introduction of metal contact 105 including metal particles to replace a metal pad arranged directly above light emitting layer 102, which does not affect light directly emitted from first semiconductor layer 101, will increase the proportion of light omitted by light emitting layer 102 within a divergence angle (e.g., twenty degrees, denoted as “a” in FIG. 1) of micro LED element 100. Consequently, an improvement in light energy power and an increase in light extraction efficiency can be expected at a viewer's eye. For example, when micro LED element 100 is incorporated into a pair of AR/VR glasses, the divergence angle of micro LED element 100 is smaller when coupling to a waveguide of the AR/VR glasses, as compared with conventional designs.

Metal contact 105 having metal particles can be formed in a variety of ways. For example, the metal particles can be deposited on first semiconductor layer 101 by sputtering or electron-beam deposition. As another example, the metal particles can be etched from a metal pad attached to first semiconductor layer 101. In some embodiments, a thickness of metal contact 105 having metal particles can be less than 100 nm. That is, the height of each metal agglomeration constituting metal contact 105 can be less than 100 nm.

In some embodiments, a size of each metal particle can be less than 500 nm. Herein, the size of an object refers to the largest measurable dimension of the object. For example, if a particle is generated as a cuboid, then the size of the particle can be the length of the longest diagonal of the cuboid. If a particle is spherically generated, then the size of the particle can be the diameter of the spheric. As can be appreciated, if a particle is ellipsoidally generated, then the size of the particle can be the length of the longest, i.e., major, axis of the ellipsoid.

In some embodiments, a distribution diameter of the metal particles in the transparent conductive layer 104 is within a range from 700 nm to 800 nm. That is, the metal particles are generated and distributed within a generally circular area with a diameter of 700 nm to 800 nm (e.g., 720 nm, 750 nm, or 780 nm) on the top surface of first semiconductor layer 101.

In some embodiments, a distribution density of the metal particles in the transparent conductive layer 104 is within a range from 10/μm² to 10000/μm². For example, there can be thirty particles generated and distributed within an area of one μm² on the top surface of first semiconductor layer 101 and the corresponding distribution density will be 30/μm².

In some embodiments, the sidewall of mesa 130 inclines so that mesa 130 gradually becomes broader from bottom to top. The inclined sidewall can be generated in other forms which are not described herein. The principal description above can also be applied to these variants.

As mesa 130 can be formed by etching at certain angles, the widths of different layers will be different due to the etching mechanism. In an etching process, the upper layers are made broader than the lower layers. In some embodiments, the diameter of the top surface of mesa 130 can be similar to, or the same as, the diameter of the bottom surface. That is, the sidewall of mesa can be almost vertical.

With further reference to FIG. 1, a sidewall surface of mesa 130 is covered with a passivation layer 107 for providing electrical insulation to the components within mesa 130. The thickness of passivation layer 107 is in a range of 3 nm to 15 nm for a bule micro LED element 100 or a green micro LED element 100, e.g., the thickness of passivation layer 107 can be 3 nm, 4 nm, 5 nm, 6 nm, 7 nm, 8 nm, 9 nm, 10 nm, 11 nm, 12 nm, 13 nm, 14 nm, or 15 nm. Alternatively, the thickness of passivation layer 107 can be several hundred nanometers for a red micro LED element 100. In some examples, passivation layer 107 is an ALD (Atomic Layer Deposition)-based layer formed by plasma-enhanced chemical vapor deposition (PECVD). A material of passivation layer 107 can be selected from one or more of Al₂O₃, HIN, SiO₂, or SiN. Passivation layer 107 is used as a thin dielectric layer. It prevents shorting of first semiconductor layer 101 and second semiconductor layer 103, each provided as an N-type epitaxial layer or P-type epitaxial layer, as described above, and passivates dangling bonds on mesa sidewalls to reduce leakage current in micro LED element 100. As shown in FIG. 1, passivation layer 107 can be extended and arranged on a bottom surface of extension part 101-2 of first semiconductor layer 101.

In some embodiments, mesa 130 may further include a transparent conductive layer 108 and a metal reflective layer 109. In some embodiments, transparent conductive layer 108 can be formed with the same material as transparent conductive layer 104. Second semiconductor layer 103 is formed on a top surface of transparent conductive layer 108. Light emitting layer 102 is formed on second semiconductor layer 103, and first semiconductor layer 101 is formed on light emitting layer 102. Transparent conductive layer 108 conductively connects second semiconductor layer 103 and metal reflective layer 109, while metal reflective layer 109 further conductively connects to contact pad 106. To improve light emission efficiency, metal reflective layer 109 is provided to reflect light upwards as viewed in FIG. 1. Metal reflective layer 109 may be made of Ag, Al, Au, etc., and coated with one or more of Cr, Ni, Pt, Ti, or Au. In some embodiments, metal reflective layer 109 is further extended to and formed on a surface of passivation layer 107, such that passivation layer 107 is provided between a sidewall of mesa 130 and metal reflective layer 109.

With further reference to FIG. 1, micro LED element 100 includes an insulating layer 110 formed on IC backplane 120. Insulating layer 110 covers IC backplane 120 and provides insulation to surface components of IC backplane 120.

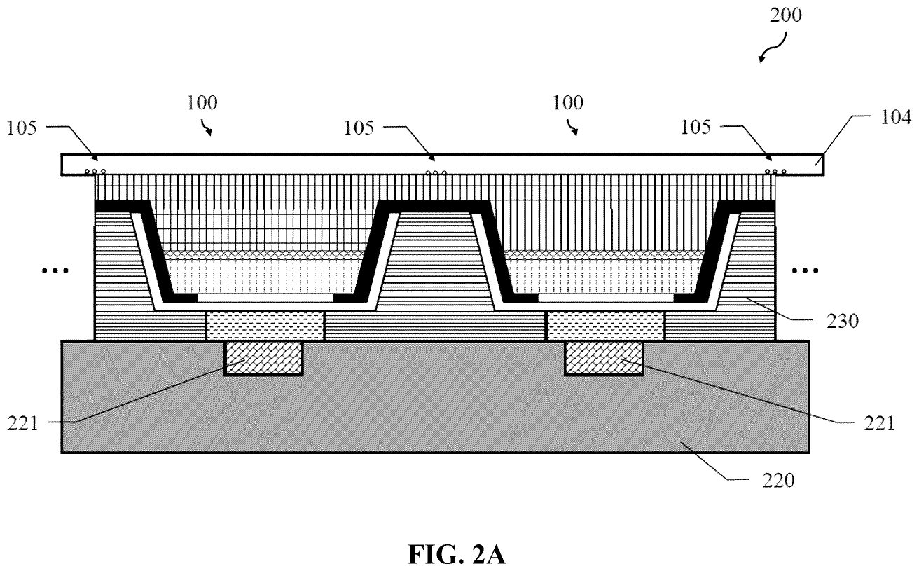

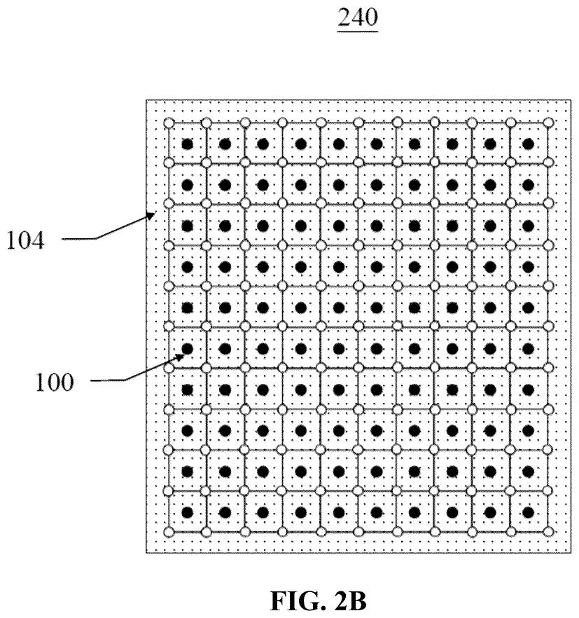

FIG. 2A illustrates a structural diagram showing a sectional view of an exemplary micro LED display panel 200, according to some embodiments of the present disclosure. As shown in FIG. 2A, micro LED display panel 200 includes an integrated circuit (IC) backplane 220 (e.g., corresponding to IC backplane 120 in FIG. 1). A plurality of electrodes 221 (e.g., corresponding to electrode 121 in FIG. 1) are embedded in IC backplane 220 such that one electrode corresponds to one micro LED element 100. Micro LED display panel 200 further includes a plurality of micro LED elements 100, as described above with reference to FIG. 1, formed net to each other. Each of the plurality of micro LED elements 100 is disposed on a top surface of IC backplane 220. In the present disclosure, the top surface of IC backplane 220 is a surface that can be provided as a substrate for arranging components. As can be appreciated, the top surface, or its corresponding bottom surface on the opposite side, is typically larger than other sides of the IC backplane. As shown in FIG. 2A, metal contacts 105 are arranged between adjacent micro LED elements 100 and embedded in transparent conductive layer 104.

It can be understood that in FIG. 2A, micro LED display panel 200 including two micro LED elements 100 is shown only for illustrative purposes. The structure shown can be extended to form a complete micro LED display panel 200. In some embodiments, micro LED display panel 200 may further include an insulating layer 230 (e.g., corresponding to insulating layer 110 in FIG. 1) formed on IC backplane 220 between the plurality of micro LED elements 100. As described above, insulating layer 230 can cover IC backplane 220 and provide insulation to surface components of IC backplane 220.

FIG. 2B illustrates a structural diagram showing a top view of an exemplary micro LED display panel 240, according to some embodiments of the present disclosure. As shown in FIG. 2B, a common transparent conductive layer 104 is shared by and formed on each micro LED elements 100.

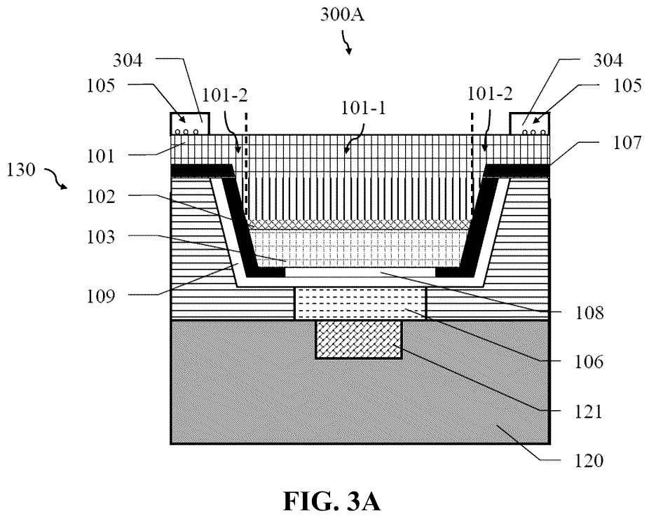

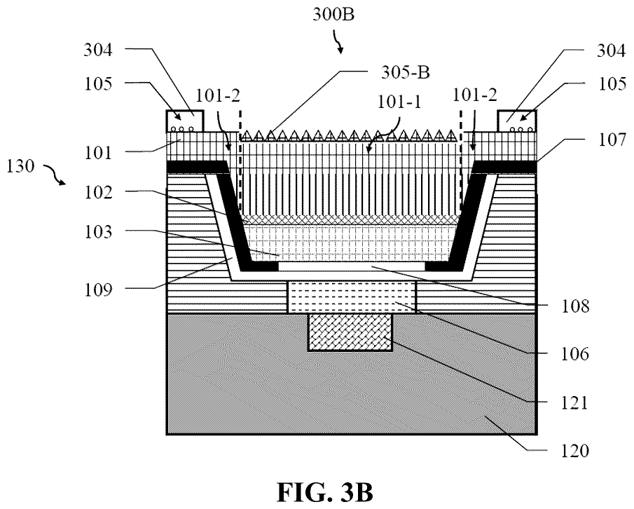

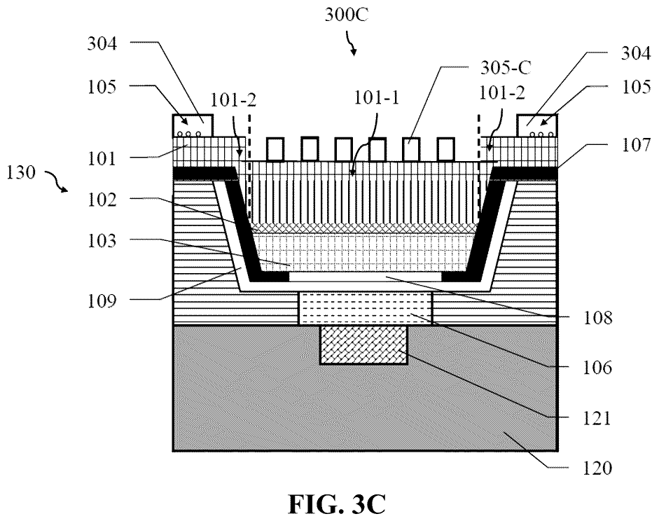

FIG. 3A illustrates a structural diagram showing a sectional view of another exemplary micro LED element 300A, according to some embodiments of the present disclosure. Referring to FIG. 3A, first semiconductor layer 101, light emitting layer 102, and second semiconductor layer 103 as described with reference to FIG. 1 are stacked from top down to form mesa 130.

As shown in FIG. 3A, micro LED element 300A includes a transparent conductive layer 304 formed on the top surface of first semiconductor layer 101 and conductively coupled to first semiconductor layer 101. Specifically, transparent conductive layer 304 is only formed on a top surface of extension part 101-2 of first semiconductor layer 101 and not on main part 101-1. Metal contact 105 embedded in transparent conductive layer 304 is conductively coupled to the top surface of extension part 101-2 of first semiconductor layer 101. Transparent conductive layer 304 can be formed with the same material as transparent conductive layer 104.

The other aspects of micro LED element 300A can be understood by referring to the description of micro LED elements 100 described above with reference to FIGS. 1 and 2 and will not be described in detail here.

FIG. 3B illustrates a structural diagram showing a sectional view of another exemplary micro LED element 300B, according to some embodiments of the present disclosure. Referring to FIG. 3B, first semiconductor layer 101, light emitting layer 102, and second semiconductor layer 103 as described with reference to FIG. 1 are stacked from top down to form mesa 130. Transparent conductive layer 304 is only formed on a top surface of extension part 101-2 of first semiconductor layer 101, and metal contact 105 embedded in transparent conductive layer 304 is conductively coupled to the top surface of extension part 101-2 of first semiconductor layer 101. Transparent conductive layer 304 can be formed with the same material as transparent conductive layer 104.

FIG. 3C illustrates a structural diagram showing a sectional view of another exemplary micro LED element 300C, according to some embodiments of the present disclosure. Micro LED element 300C can be similar to micro LED element 300B except for aspects described below.

In some embodiments, a top surface of main part 101-1 of first semiconductor layer 101 is rough. For example, the top surface of main part 101-1 can be formed with microstructures 305-B, e.g., triangles shown in FIG. 3B, to reduce total reflections at the top surface of main part 101-1. The roughness of the top surface will improve light extraction of micro LED element 300B. With further reference to FIG. 3C, the roughness of the top surface of main part 101-1 can be effected with microstructures 305-C of photonic crystals which are illustrated as crenels. Photonic crystals can be used to improve light extraction and beam profile of micro LED element 300C. As can be appreciated, microstructures 305-B and 305-C in FIGS. 3B and 3C respectively are enlarged for illustrating the principles of the present disclosure, and their actual sizes can be different from those illustrated in the figures. In some embodiments, microstructures 305-B and 305-C can be formed by, e.g., etching the surface of main part 101-1 and hence be formed of the same material as main part 101-1. In some embodiments, the surface of main part 101-1 can be formed by photolithography and plasma etching.

The other aspects of micro LED elements 300B and 300C can be understood by referring to the description of micro LED elements 100 described above with reference to FIGS. 1 and 2 and micro LED elements 300A described above with reference to FIG. 3A and will not be described in detail here.

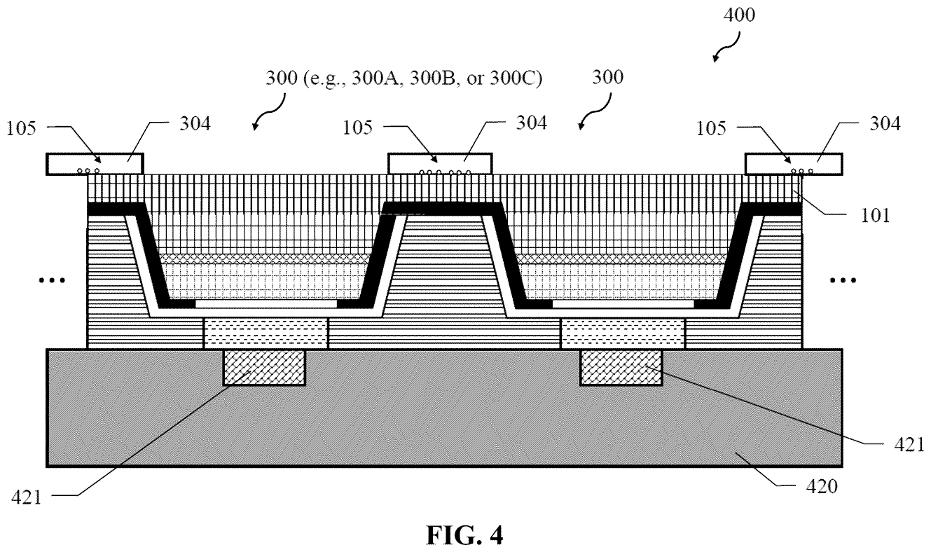

FIG. 4 illustrates a structural diagram showing a sectional view of an exemplary micro LED display panel 400, according to some embodiments of the present disclosure. As shown in FIG. 4, micro LED display panel 400 includes an integrated circuit (IC) backplane 420 (e.g., corresponding to IC backplane 120 in FIGS. 1 and 3A to 3C). A plurality of electrodes 421 (e.g., corresponding to electrode 121 in FIGS. 3A to 3C) are embedded in IC backplane 420 such that one electrode corresponds to one micro LED element 300. Micro LED display panel 400 further includes a plurality of micro LED elements 300 (e.g., micro LED element 300A, 300B, or 300C as described above with reference to FIGS. 3A to 3C) formed next to each other. Each of the plurality of micro LED elements 300 is disposed on a top surface of IC backplane 420. In the present disclosure, the top surface of IC backplane 420 is a surface that can be provided as a substrate for arranging components. As can be appreciated, the top surface, or its corresponding bottom surface on the opposite side, is typically larger than other sides of the IC backplane.

It can be understood that in FIG. 4, micro LED display panel 400 including two micro LED elements 300 is shown only for illustrative purposes. The structure shown can be extended to form a complete micro LED display panel 400. As shown in FIG. 4, transparent conductive layers 304 of adjacent micro LED elements 300 are formed together and their respective metal contacts 105 are embedded in the joint transparent conductive layer 304. That is, transparent conductive layers 304 of different micro LED elements 300 can be formed in a single process (e.g., disposition) and shared by adjacent micro LED elements 300.

The other aspects of micro LED display panel 400 can be understood by referring to the description of micro LED display panel 200 and will not be described in detail here.

In some embodiments, micro LED display panel 400 may also include micro LED elements that do not possess a transparent conductive layer (not shown) or micro LED elements with incomplete transparent conductive layer (not shown but described hereinafter). As first semiconductor layers 101 of all of micro LED elements 300 are formed as a continuous layer, the tops of all micro LED elements 300 are electrically connected, and the driving signal to a target micro LED element 300 without transparent conductive layer 304 can be received via corresponding electrode 421 of the target micro LED element 300 and continuous first semiconductor layer 101 electrically connected to transparent conductive layer 304, for example. In the present disclosure, such arrangement of transparent conductive layer 304 is called a sparse arrangement of the transparent conductive layer, and the degree of sparsity can be determined according to actual needs or physical restrictions. The sparse arrangement can reduce a shading effect and thus increase the light extraction from the mesa.

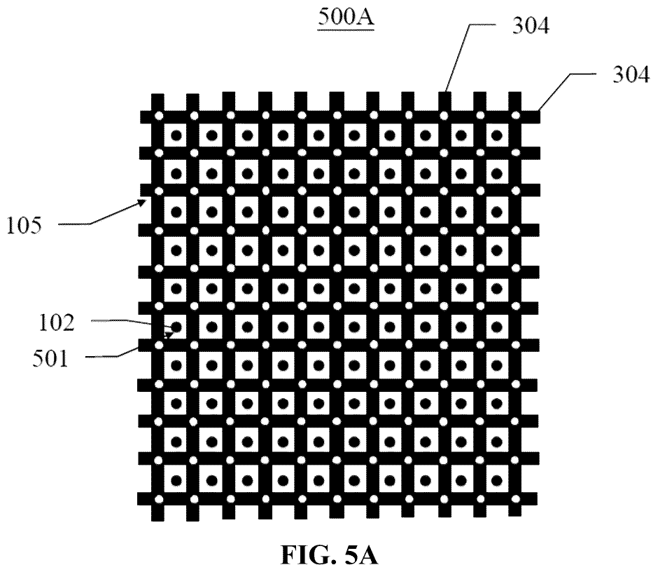

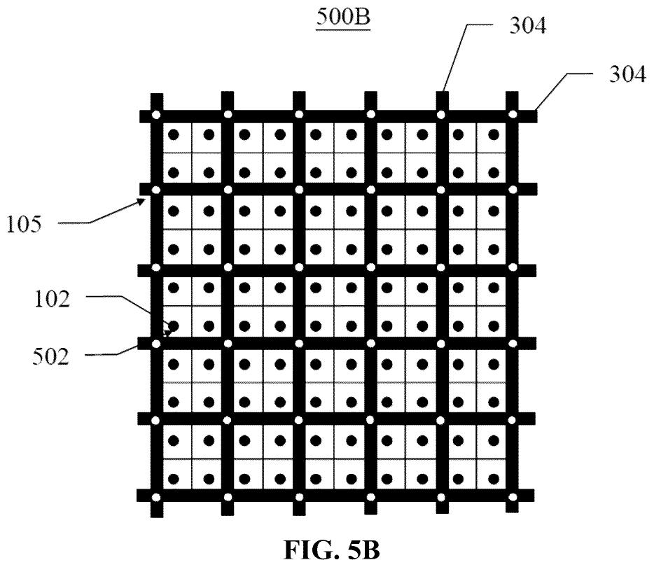

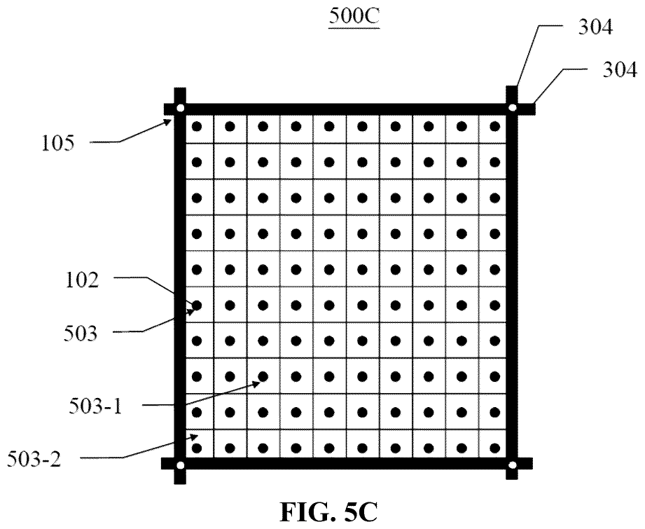

In some embodiments, transparent conductive layers 304 can be deposited on extension part 101-2 of first semiconductor layer 101 of adjacent micro LED elements 300. FIG. 5A illustrates a structural diagram showing a top view of another exemplary micro LED display panel 500A, according to some embodiments of the present disclosure. Light emitting layer 102 of each micro LED element 501 is surrounded by horizontal and vertical transparent conductive layers 304 when seen above. That is, micro LED element 501 is a micro LED element with a completely transparent conductive layer. Metal contacts 105 can be embedded in the intersections of two transparent conductive layers 304.

In some embodiments, transparent conductive layers 304 can be deposited in the sparse arrangement. FIG. 5B illustrates a structural diagram showing a top view of another exemplary micro LED display panel 500B, according to some embodiments of the present disclosure. Transparent conductive layers 304 are disposed, horizontally and vertically, every two micro LED elements 502. Light emitting layers 102 of a group of four micro LED elements 502 are surrounded by transparent conductive layer 304 when seen above. Metal contacts 105 can be embedded in the intersections of two transparent conductive layers 304. FIG. 5C illustrates a structural diagram showing a top view of another exemplary micro LED display panel 500C, according to some embodiments of the present disclosure. Transparent conductive layers 304 are disposed at the edges of this array of micro LED elements 503. Light emitting layers 102 of this array of micro LED elements 503 are surrounded by transparent conductive layers 304 only at the edges when viewed from above. Metal contacts 105 can be embedded in the intersections of two transparent conductive layers 304 at the edges. As shown in FIG. 5C, micro LED elements 503-1 are micro LED elements not at the edges of the array and do not possess a transparent conductive layer, while micro LED elements 503-2 are micro LED elements at the edge of the array and have partial transparent conductive layers, as described above.

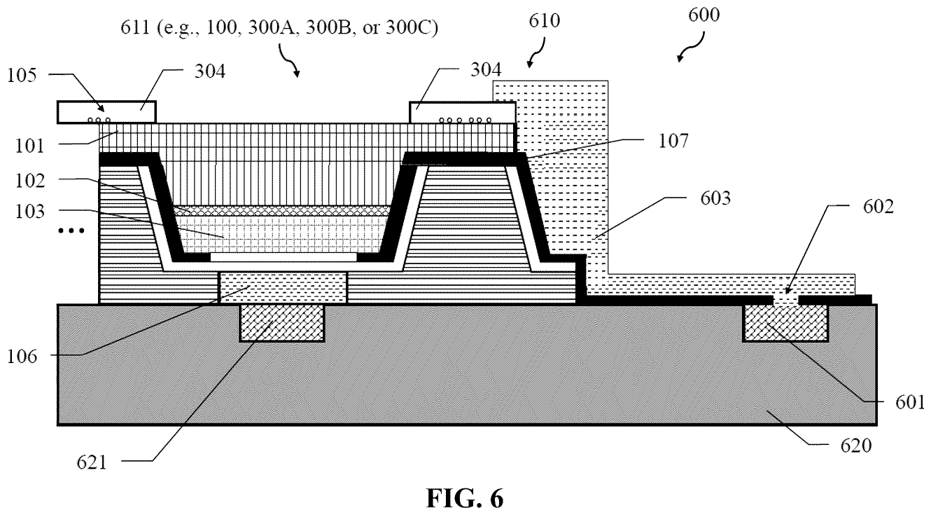

FIG. 6 illustrates a structural diagram showing a sectional view of another exemplary micro LED display panel 600, according to some embodiments of the present disclosure. As shown in FIG. 6, a connecting part 610 at an edge (e.g., right edge) of micro LED display panel 600 is used for conductively coupling micro LED elements 611 (e.g., corresponding to micro LED element 100, 300A, 300B, or 300C described above with reference to FIGS. 1, and 3A to 3C) on an IC backplane 620 to an electrode 601 (e.g., a common pad). At the edge of micro LED display panel 600, the deposited passivation layer 107 of micro LED elements 611 can be extended to the top surface of IC backplane 620 leaving a hole 602 above electrode 601. Above passivation layer 107, a connecting part 610 comprising a conductive layer 603 is further formed, which also fills in hole 602 and conductively connects with electrode 601 and transparent conductive layer 304.

As such, transparent conductive layer 304 of each micro LED element 600 is connected to electrode 601 and contact pad 106 of each micro LED element 611 is connected to electrode 621 of IC backplane 620, respectively. This enables first semiconductor layer 101 and second semiconductor layer 103 of each micro LED element 611 to receive signals from IC backplane 620. As a consequence, light emitting layer 102 between first semiconductor layer 101 and second semiconductor layer 103 of each micro LED element 611 can be driven by IC backplane 620.

The other aspects of micro LED display panel 600 can be understood by referring to micro LED display panel 200 described above with reference to FIG. 2A and will not be described in detail here.

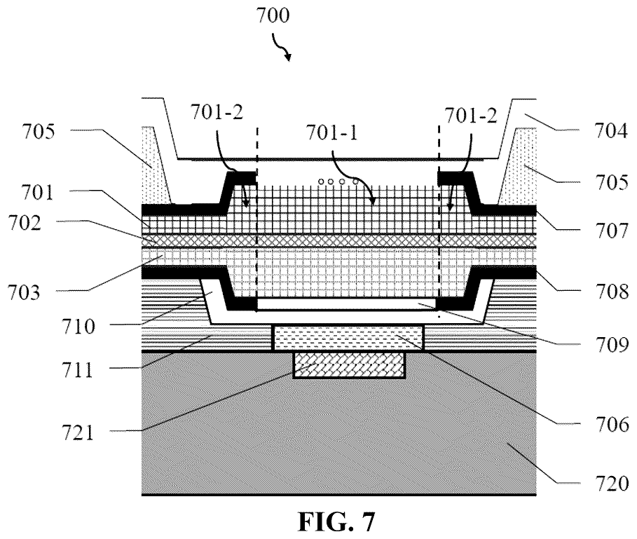

FIG. 7 illustrates a structural diagram showing a sectional view of another exemplary micro LED element 700, according to some embodiments of the present disclosure. Referring to FIG. 7, micro LED element 700 includes a first semiconductor layer 701, a light emitting layer 702, and a second semiconductor layer 703. First semiconductor layer 701, light emitting layer 702, and second semiconductor layer 703 are stacked from top down to form a mesa with a different shape compared to that shown in FIGS. 1, and 3A-3C. As shown in FIG. 7, the mesa is formed into an olive shape with respective first semiconductor layer 701 and second semiconductor layer 703 decreasing in thickness at their ends and on either side of light emitting layer 702. Hence, the corresponding mid-portions of first semiconductor layer 701 and second semiconductor layer 703 are thicker than corresponding end portions. First semiconductor layer 701 includes a main part 701-1 and an extension part 701-2. Main part 701-1 is configured to pass light generated by light emitting layer 702. Extension part 701-2 can be connected to extension part 701-2 of first semiconductor layer 701 of an adjacent micro LED element (not shown). Main part 701-1 and extension part 701-2 of first semiconductor layer 701 are illustrated as divided by the dashed lines shown in FIG. 7.

In some embodiments, second semiconductor layer 703 can be a P-type epitaxial layer or an N-type epitaxial layer. First semiconductor layer 701 is an N-type epitaxial layer or a P-type epitaxial layer. A material of first semiconductor layer 701 is selected from one or more of GaN, InGaN, AlInGaN, AlGaN, GaP, AlGaInP, or AlInP. Light emitting layer 702 is a quantum well layer. A material of light emitting layer 702 is selected from one or more of InGaN, AlGaN, AlInGaN, InGaP or AlGaInP. First semiconductor layer 701 and second semiconductor layer 703 have opposite conductive types. That is, if first semiconductor layer 701 is a P-type epitaxial layer, then second semiconductor layer 703 is an N-type epitaxial layer; and if first semiconductor layer 701 is an N-type epitaxial layer, then second semiconductor layer 703 is a P-type epitaxial layer. A material of second semiconductor layer 703 is selected from one or more of AlInP, AlGaInP, GaP, GaN, InGaN, AlInGaN or AlGaN.

As shown in FIG. 7, micro LED element 700 further includes a transparent conductive layer 704 formed on a top surface of first semiconductor layer 701 and conductively coupled to first semiconductor layer 701. Transparent conductive layer 704 can be connected to an electrode (not shown) of an IC backplane 720. In some embodiments, transparent conductive layer 704 is provided as a TCO (transparent conductive oxide) layer, for example, an ITO (Indium Tin Oxide) layer, an AZO (Aluminium doped Zinc Oxide) layer, a GZO (Gallium doped Zinc Oxide), an ATO (Antimony doped Tin Oxide) layer, an FTO (Fluorine doped Tin Oxide) layer, or the like.

Micro LED element 700 further includes a metal pad 705 embedded in transparent conductive layer 704. Specifically, metal pad 705 is arranged above extension part 701-2 of first semiconductor layer 701. Metal pad 705 can be used to increase current expansion between adjacent micro LED elements 700 and subsequently improve current spreading across the whole Micro LED array formed by micro LED elements 700. In some embodiments, metal pad 705 can also be deposited on passivation layer 707, and the benefits described above with the deposition on first semiconductor layer can also be expected here.

As shown in FIG. 7, micro LED element 700 further includes a contact pad 706 that is connected to an electrode 721 (e.g., a Cu pad) of IC backplane 720. Hence, transparent conductive layer 704 and contact pad 706 are connected to two electrodes of IC backplane 720. This enables first semiconductor layer 701 and second semiconductor layer 703 to receive signals from IC backplane 720. As a consequence, light emitting layer 702 between first semiconductor layer 701 and second semiconductor layer 703 can be driven by the signals from IC backplane 720.

As shown in FIG. 7, light emitting layer 702 separates micro LED element 700 into two isolated parts. As for the part above light emitting layer 702, a passivation layer 707 is formed on a sidewall surface of first semiconductor layer 701. As for the part below light emitting layer 702, a passivation layer 708 is formed on a sidewall surface of second semiconductor layer 703. Passivation layers 707 and 708 can provide electrical insulation to the component they cover. The thickness of passivation layer 707 (708) is in a range of 3 nm to 15 nm for a bule micro LED element 700 or a green micro LED element 700, e.g., the thickness of passivation layer 707 (708) can be 3 nm, 4 nm, 5 nm, 6 nm, 7 nm, 8 nm, 9 nm, 10 nm, 11 nm, 12 nm, 13 nm, 14 nm, or 15 nm. Alternatively, the thickness of passivation layer 707 (708) can be several hundred nanometers for a red micro LED element 700. In some examples, passivation layer 707 (708) is an ALD-based layer formed by plasma-enhanced chemical vapor deposition (PECVD). A material of passivation layer 707 (708) can be selected from one or more of Al₂O₃, HfN, SiO₂, or SiN. Passivation layer 707 (708) is used as a thin dielectric layer. It prevents shorting of first semiconductor layer 701 and second semiconductor layer 703, each provided as an N-type epitaxial layer or P-type epitaxial layer as described above, and passivates dangling bonds on sidewalls to reduce leakage current in micro LED element 700. As shown in FIG. 7, passivation layer 707 can also be deposited in a region of the top surface of first semiconductor layer 701. In some embodiments, in the process of depositing transparent conductive layer 704, it can be then formed on the top surface of first semiconductor layer 701 in the region that is not deposited with passivation layer 707.

In some embodiments and with reference to the above description of object size as used herein, a size of each metal particle can be less than 500 nm.

In some embodiments, a distribution diameter of the metal particles in transparent conductive layer 704 is within a range from 700 nm to 800 nm. That is, the metal particles are generated and distributed within a generally circular area with a diameter of 700 nm to 800 nm (e.g., 720 nm, 750 nm, or 780 nm) on the top surface of passivation layer 707.

In some embodiments, a distribution density of the metal particles in transparent conductive layer 704 is within a range from 10/μm² to 10000/μm². For example, there can be thirty particles generated and distributed within an area of one μm² on the top surface of passivation layer 707.

Still referring to FIG. 7, micro LED element 700 further includes a transparent conductive layer 709 for conductively connecting second semiconductor layer 703 and contact pad 706 through a metal reflective layer 710 further described below. For example, contact pad 706 can be formed below transparent conductive layer 709. In some embodiments, second semiconductor layer 703 is formed on a top surface of transparent conductive layer 709. Light emitting layer 702 is formed on second semiconductor layer 703, and first semiconductor layer 701 is formed on light emitting layer 702. In some embodiments, transparent conductive layer 709 can be formed with the same material as transparent conductive layer 704.

Micro LED element 700 further includes metal reflective layer 710 formed on a bottom surface of second transparent conductive layer 709, wherein contact pad 706 is formed on a bottom surface of the metal reflective layer 710. To improve light emission efficiency, metal reflective layer 710 is provided to reflect light upwards as viewed in FIG. 7. Metal reflective layer 710 may be made of Ag, Al, Au, etc., and coated with one or more of Cr, Ni, Pt, Ti, or Au. In some embodiments, metal reflective layer 710 is further extended to and formed on a surface of passivation layer 708. Passivation layer 708 is provided between metal reflective layer 710 and second semiconductor layer 703.

With further reference to FIG. 7, micro LED element 700 further includes an insulating layer 711 formed on IC backplane 720. Insulating layer 711 covers IC backplane 720 and provides insulation to surface components of IC backplane 720. The other aspects of micro LED element 700 can be understood by referring to the description of micro LED elements 100 and micro LED elements 300A, 300B, and 300C described above with reference to FIGS. 1, and 3A to 3C and will not be described in detail here.

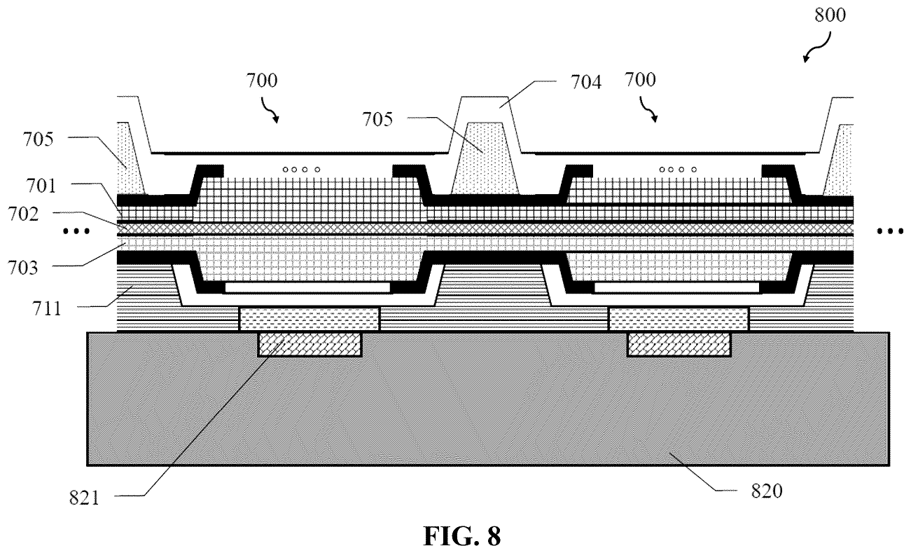

FIG. 8 illustrates a structural diagram showing a sectional view of another exemplary micro LED display panel 800, according to some embodiments of the present disclosure. As shown in FIG. 8, micro LED display panel 800 includes an IC backplane 820 (e.g., corresponding to IC backplane 720 in FIG. 7). A plurality of electrodes 821 (e.g., corresponding to electrode 721 in FIG. 7) are embedded in IC backplane 820 such that one electrode corresponds to one micro LED element 700. Micro LED display panel 800 further includes a plurality of micro LED elements 700 as described above with reference to FIG. 7. Each of the plurality of micro LED elements 700 is disposed on a top surface of IC backplane 820. The top surface of IC backplane 820 is a surface that can be provided as a substrate for arranging components. As can be appreciated, the top surface, or its corresponding bottom surface on the opposite side, is typically larger than other sides of the IC backplane. Metal pad 705 embedded in transparent conductive layer 704 and between adjacent micro LED elements 700 can be used to improve current spreading across the whole micro LED array, e.g., micro LED display panel 800, formed by micro LED elements 700. As shown in FIG. 8, each of first semiconductor layer 701, light emitting layer 702, and second semiconductor layer 703 of micro LED display panel 800 forms a continuous layer. That is, first semiconductor layers 701, light emitting layers 702, or second semiconductor layers 703 of micro LED elements 700 are contiguous in micro LED display panel 800.

It can be understood that in FIG. 8, micro LED display panel 800 including two micro LED elements 700 is shown only for illustrative purposes. The structure shown can be extended to form a complete micro LED display panel 800. Micro LED display panel 800 further includes an insulating layer 711 formed on IC backplane 820 between each of the plurality of micro LED elements 700. Insulating layer 711 can cover IC backplane 820 and provides insulation to surface components of IC backplane 820. As can be appreciated, each micro LED element 700 of micro LED display panel 800 can be connected to two electrodes of IC backplane 820 in a similar manner to that shown in FIG. 6.

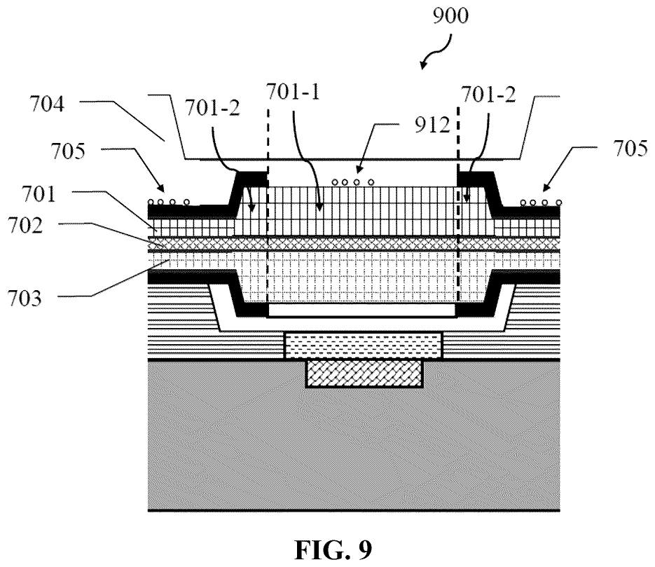

FIG. 9 illustrates a structural diagram showing a sectional view of another exemplary micro LED element 900, according to some embodiments of the present disclosure. As shown in FIG. 9, micro LED element 900 includes a metal contact 912 embedded in transparent conductive layer 704 which acts as an ohmic contact to increase the electrical conductivity between first semiconductor layer 701 and transparent conductive layer 704. Metal contact 912 can be formed on a top surface of main part 701-1 of first semiconductor layer 701. Micro LED element 900 is otherwise the same as micro LED element 700 except for metal contact 912 described here.

As illustrated in FIG. 9, metal contact 912 includes a plurality of metal particles (also referred to as “metal agglomeration”, which is denoted by hollow circles) conductively coupled to the top surface of first semiconductor layer 701. For example, micro LED element 900 may be a red micro LED element used to represent a red pixel or sub-pixel. In some embodiments, the presence of a metal contact as a whole pad on the red micro LED element can result in an undesirable shading effect, a decrease in light extraction, or a blurred far-field beam profile. With the introduction of metal contact 912 composed of metal particles, the contact area with first semiconductor layer 701 can be reduced while maintaining the ohmic-contact.

Moreover, the introduction of metal contact 912 including metal particles will increase the proportion of light within a divergence angle (e.g., twenty degrees) of micro LED element 900. Consequently, an improvement in light energy power and an increase in light extraction efficiency can be expected at a viewer's eye. For example, when micro LED element 900 is incorporated into a pair of AR/VR glasses, the divergence angle of micro LED element 900 is smaller when coupling to a waveguide of the AR/VR glasses, as compared with conventional designs.

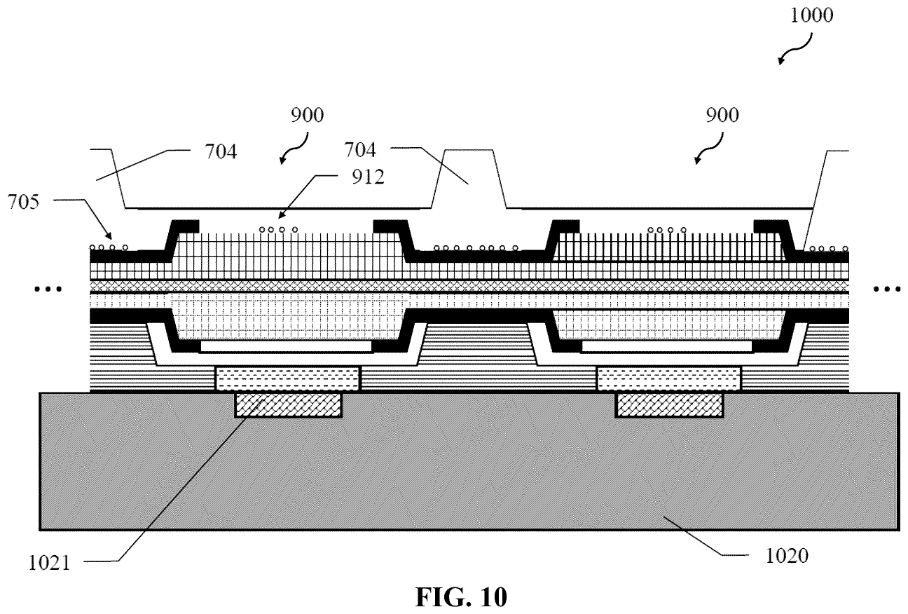

FIG. 10 illustrates a structural diagram showing a sectional view of another exemplary micro LED display panel 1000, according to some embodiments of the present disclosure. Similar to micro LED display panel 800 shown in FIG. 8, micro LED display panel 1000 includes an IC backplane 1020 on which are disposed a plurality of micro LED elements 900 (FIG. 9). A plurality of electrodes 1021 are embedded in IC backplane 1020 such that one electrode corresponds to one micro LED element 900. Metal contact 912, described above with reference to FIG. 9, is embedded in transparent conductive layer 704 and can be used to improve current spreading across the whole micro LED array formed by micro LED elements 900. It is appreciated that in FIG. 10, micro LED display panel 1000 including two micro LED elements 900 is shown only for illustrative purposes. The structure shown can be extended to form a complete micro LED display panel 1000. The other aspects of micro LED display panel 1000 can be understood by referring to the description of micro LED display panel 800 and will not be described in detail here.

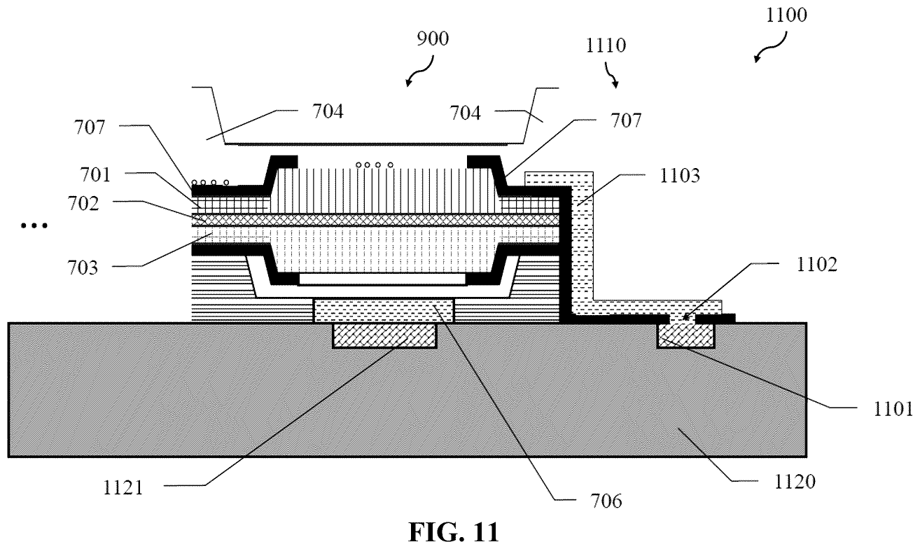

FIG. 11 illustrates a structural diagram showing a sectional view of an exemplary micro LED display panel 1100, according to some embodiments of the present disclosure. As shown in FIG. 11, a connecting part 1110 at an edge (e.g., right edge) of micro LED display panel 1100 is used for conductively coupling the micro LED elements 900 (FIG. 9) on an IC backplane 1120 to an electrode 1101 (e.g., a common pad). At the edge of micro LED display panel 1100, the deposited passivation layer 707 of micro LED elements 900 can be extended to the top surface of IC backplane 1120 leaving a hole 1102 above electrode 1101. Above passivation layer 707 of connecting part 1110, a conductive layer 1103 is further formed, which also fills in hole 1102 and conductively connects with electrode 1101 and transparent conductive layer 704.

As such, transparent conductive layer 704 of each micro LED element 900 is connected to electrode 1101 and contact pad 706 of each micro LED element 900 is connected to electrode 1121 of IC backplane 1120, respectively. This enables first semiconductor layer 701 and second semiconductor layer 703 of each micro LED element 900 to receive signals from IC backplane 1120. As a consequence, light emitting layer 702 between first semiconductor layer 701 and second semiconductor layer 703 of each micro LED element 900 can then be driven by IC backplane 1120.

The other aspects of micro LED display panel 1100 can be understood by referring to micro LED display panel 1000 described above with reference to FIG. 10 and will not be described in detail here.

In some embodiments, each micro LED element (e.g., micro LED element 100 in FIG. 1, micro LED element 300A in FIG. 3A, micro LED element 300B in FIG. 3B, micro LED element 300C in FIG. 3C, micro LED element 700 in FIG. 7, or micro LED element 900 in FIG. 9) herein has a very small volume. The light emitting area of the micro LED display panel (e.g., micro LED display panel 200 in FIG. 2A, micro LED display panel 400 in FIG. 4, micro LED display panel 800 in FIG. 8, or micro LED display panel 1000 in FIG. 10) is very small, such as 1 mm×1 mm, 3 mm×5 mm, etc. In some embodiments, the light emitting area of the micro LED display panel can be less than or equal to or near 0.15 cm², 0.25 cm², or 1 cm². In some embodiments, the light emitting area is the area of the micro LED array area in the micro LED display panel. Each micro LED display panel disclosed herein, e.g., micro LED display panel 700, includes one or more micro LED elements that form a pixel array in which the micro LED elements are pixels, such as a 1600×1200, 680×480, or 1920×1080-pixel array. The diameter of each micro LED is in the range of about 200 nm to 2 μm.

Different types of micro LED panels can be provided. For example, the resolution of a display panel can range typically from 8×8 to 3840×2160. Common display resolutions include QVGA (Quarter Video Graphics Array) with 320×240 resolution and an aspect ratio of 4:3, XGA (Extended Graphics Array) with 1024×768 resolution and an aspect ratio of 4:3, D (Definition) with 1280×720 resolution and an aspect ratio of 16:9, FHD (Full High Definition) with 1920×1080 resolution and an aspect ratio of 16:9, UHD (Ultra High Definition) with 3840×2160 resolution and an aspect ratio of 16:9, and 4K with 4096×2160 resolution. There can also be a wide variety of pixel sizes, ranging from sub-micron and below to 10 mm and above. The size of the overall display region can also vary widely, ranging from diagonals as small as tens of microns or less up to hundreds of inches or more.

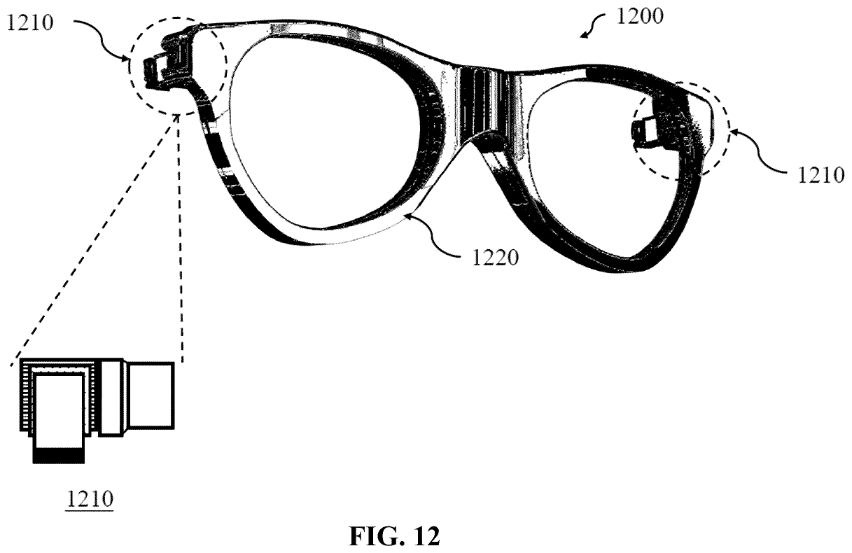

FIG. 12 illustrates an exemplary display device, according to some embodiments of the present disclosure. As shown in FIG. 12, a near eye display (NED) 1200, for example AR glasses, includes a pair of polychrome projectors 1210 and a frame 1220 for securing polychrome projectors 1210. NED 1200 may also include other components which are omitted here for the purpose of clearly illustrating the configuration of NED 1200. Each polychrome projector 1210 can be arranged at an end of a temple (not shown) of NED 1200, respectively. A power system and a processing system to drive polychrome projectors 1210 can be embedded in the temple. Images rendered by each polychrome projector 1210 can be captured by respective eyes of a viewer (not shown), which can be used to create a virtual scene or an augmented scene for the viewer. In some embodiments, the term “render” may also be referred to as “display,” “show” or an equivalent. Each polychrome projector 1210 may include three micro LED panels (e.g., each corresponding to micro LED display panel 200 in FIG. 2A, micro LED display panel 400 in FIG. 4, micro LED display panel 600 in FIG. 6, micro LED display panel 800 in FIG. 8, or micro LED display panel 1000 in FIG. 10) of different colors and a combiner (e.g., a combining prism). Combiner can be used to combine (also referred to as “compositing”) the images rendered the three micro LED panels to a composite image.

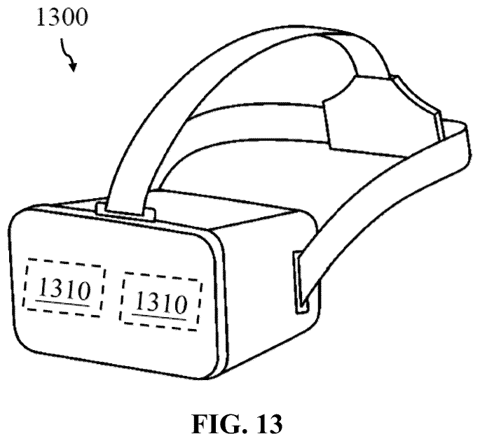

FIG. 13 illustrates another exemplary display device, according to some

embodiments of the present disclosure. As shown in FIG. 13, a head-mounted virtual reality device 1300 includes two micro LED panels 1310 (e.g., corresponding to micro LED display panel 200 in FIG. 2A, micro LED display panel 400 in FIG. 4, micro LED display panel 600 in

FIG. 6, micro LED display panel 800 in FIG. 8, or micro LED display panel 1000 in FIG. 10). Although not shown, head-mounted virtual reality device 1300 may also include a central processing unit (CPU), a graphic processing unit (GPU) acting as a signal source, and other related circuitries. The introduction of micro LED panels that embody the micro LED elements described above in head-mounted virtual reality device 1300 can improve the lighting efficiency thereof, hence reducing energy consumption and improving imaging quality.

It should be noted that the relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as exemplary only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

In the drawings and specification, there have been disclosed exemplary embodiments. However, many variations and modifications can be made to these embodiments. Accordingly, although specific terms are employed, they are used in a generic and descriptive sense only and not for purposes of limitation.

What is claimed is:

1. A micro LED element, comprising:
a first semiconductor layer, a light emitting layer, and a second semiconductor layer stacked from top down, wherein the first semiconductor layer comprises:
a main part for passing light generated by the light emitting layer; and
an extension part for connecting to an extension part of a first semiconductor layer of an adjacent micro LED element; and
a metal contact comprising a plurality of metal particles arranged on or above the extension part of the first semiconductor layer.

2. The micro LED element according to claim 1, wherein a thickness of the metal contact is less than 100 nm.

3. The micro LED element according to claim 1, wherein a size of each of the plurality of metal particles is less than 500 nm.

4. The micro LED element according to claim 1, further comprising:
a transparent conductive layer formed on a top surface of the first semiconductor layer, wherein the metal contact is embedded in the transparent conductive layer.

5. The micro LED element according to claim 4, wherein a distribution diameter of the plurality of metal particles in the transparent conductive layer is within a range from 700 nm to 800 nm.

6. The micro LED element according to claim 4, wherein a distribution density of the plurality of metal particles in the transparent conductive layer is within a range from 10/μm² to 10000/μm².

7. The micro LED element according to claim 4, wherein the transparent conductive layer is formed on a top surface of the extension part of the first semiconductor layer, and the metal contact is conductively coupled to the top surface of the extension part of the first semiconductor layer.

8. The micro LED element according to claim 7, wherein the main part of the first semiconductor layer comprises a rough top surface.

9. The micro LED element according to claim 8, wherein the rough top surface is formed with photonic crystals.

10. The micro LED element according to claim 4, wherein the first semiconductor layer, the light emitting layer, and the second semiconductor layer are stacked as a mesa; and the micro LED element further comprises:
a passivation layer formed on a sidewall surface of the mesa and a bottom surface of the extension part of the first semiconductor layer.

11. The micro LED element according to claim 10, wherein the passivation layer is an ALD (Atomic Layer Deposition)-based layer.

12. The micro LED element according to claim 10, wherein the transparent conductive layer is a first transparent conductive layer, the mesa further comprising: a second transparent conductive layer formed on a bottom surface of the second semiconductor layer.

13. The micro LED element according to claim 12, further comprising:
a metal reflective layer formed on a bottom surface of the second transparent conductive layer; and
a contact pad formed on a bottom surface of the metal reflective layer and conductively coupled to the second semiconductor layer.

14. The micro LED element according to claim 4, wherein the second semiconductor layer comprises an extension part for connecting to the extension part of the second semiconductor layer of an adjacent micro LED element, and
wherein the micro LED element further comprises:
a first passivation layer formed on the extension part of the first semiconductor layer; and
a second passivation layer formed on a bottom surface of the second semiconductor layer.

15. The micro LED element according to claim 14, wherein at least one of the first passivation layer and the second passivation layer is an ALD-based layer.

16. The micro LED element according to claim 14, wherein the transparent conductive layer is a first transparent conductive layer, and the micro LED element further comprises:
a second transparent conductive layer formed on a bottom surface of the second semiconductor layer; and
a contact pad formed below the second transparent conductive layer and conductively coupled to the second semiconductor layer.

17. The micro LED element according to claim 16, further comprising: a metal reflective layer formed on a bottom surface of the second transparent conductive layer, wherein the contact pad is formed on a bottom surface of the metal reflective layer.

18. The micro LED element according to claim 17, wherein the metal reflective layer is further formed on a surface of the second passivation layer, the second passivation layer being provided between the metal reflective layer and the second semiconductor layer.

19. The micro LED element according to claim 14, wherein the metal contact is a first metal contact, and the micro LED element further comprises: a second metal contact embedded in the transparent conductive layer, the second metal contact comprising a plurality of metal particles formed on a top surface of the main part of the first semiconductor layer.

20. A micro LED display panel, comprising:
an integrated circuit (IC) backplane comprising a common pad and a plurality of bottom contacts; and
a plurality of micro LED elements, each according to claim 1, disposed on a top surface of the IC backplane, each of the micro LED elements comprising a transparent conductive layer formed on a top surface of the first semiconductor layer; and a contact pad conductively coupled to the second semiconductor layer, wherein:
the transparent conductive layer is conductively coupled to the common pad; and
the contact pad is formed to contact a corresponding bottom contact of the plurality of bottom contacts.

21. A display device, comprising a micro LED display panel, wherein the micro LED display panel comprises:
an integrated circuit (IC) backplane comprising a common pad and a plurality of bottom contacts; and
a plurality of micro LED elements, each according to claim 1, disposed on a top surface of the IC backplane, each of the micro LED elements comprising a transparent conductive layer formed on a top surface of the first semiconductor layer; and a contact pad conductively coupled to the second semiconductor layer, wherein:
the transparent conductive layer is conductively coupled to the common pad; and
the contact pad is formed to contact a corresponding bottom contact of the plurality of bottom contacts.
